(19) United States
(12) Patent Application Publication
(10) Pub. No.: US 2018/0132353 A1
(43) Pub. Date: May 10, 2018

(54) ELECTRONIC BOARD AND ASSOCIATED MANUFACTURING METHOD

(71) Applicant: THALES, COURBEVOIE (FR)

(72) Inventors: Eric PREDON, LOCMARIA PLOUZANE (FR); Pierre BELEC, PLOUGONVELIN (FR)

(21) Appl. No.: 15/574,133

(22) PCT Filed: May 27, 2016
(86) PCT No.: PCT/EP2016/062048

§ 371 Date: Nov. 14, 2017

(30) Foreign Application Priority Data
May 29, 2015 (FR) 15/01114

(51) Int. Cl. H05K 1/14; H05K 1/02; H05K 3/22

(52) U.S. Cl. CPC H05K 1/144; H05K 3/22; H05K 1/0203

(57) ABSTRACT

An electronic circuit board comprising an assembly of a printed circuit board comprises a first face receiving at least one electronic component, and a heat sink, the printed circuit board and the heat sink stacked in a stacking direction, the heat sink fixed to the printed circuit board on a second face opposite the first face, the heat sink comprising a base, in the form of a plate, and reliefs extending from a flat surface of the base, the reliefs intended to increase the contact surface between the heat sink and a flow of air relative to the contact surface between the base and the flow of air, the base interposed between the printed circuit board and the reliefs in the stacking direction, the heat sink fixed directly to the printed circuit board by gluing only and wherein the heat sink is of a single piece.

The invention relates to the cooling of electronic circuit boards plugged into a cabinet or backplane, also called drawer or rack. The invention is of particular use for electronic equipment items, in particular the power supply boards, whose components heat up significantly and which require a rapid discharging of the heat. The invention is particularly advantageous for embedded electronic equipment items, in particular cooled by fanned air.

There are, for example, computers comprising several electronic circuit boards arranged parallel to one another in the cabinet. In order to ensure the maintenance of the equipment item, the various boards are dismountable. The mounting and the dismounting of the boards is done by translation thereof in grooves or runners of the cabinet.

Printed circuit board is the term given to a bare printed circuit board, that is to say one without electronic components and with no heat sink device, and an electronic circuit board is a printed circuit board equipped with a heat sink and one or more electronic components. A printed circuit board comprises or is an assembly of a plurality of conductive layers separated in pairs by a layer of insulating material or an assembly of at least one conductive layer and one insulating layer. The conductive layers each comprise conductive tracks. They are, for example, obtained by etching. In operation, the components of the electronic circuit board can dissipate a lot of heat. This heat has to be discharged in order to maintain a suitable operating temperature that does not exceed an acceptable maximum value.

Several solutions have been considered for the cooling of electronic equipment items: cooling by thermal convection and cooling by thermal conduction.

Thermal convection consists in placing a hot body in contact with a fluid, preferably set in motion relative to the board so as to improve the heat exchange between the hot components and the cold fluid.

Thermal conduction is a thermal transfer mode resulting from a temperature difference between two zones of one and the same medium or between two different media in contact.

One known solution for the cooling of electronic circuit boards consists in equipping the printed circuit board with a thermal drain in the form of a plate produced in a material with strong thermal conductivity, such as copper or aluminium for example. The plate has substantially the same surface area as the printed circuit board and is parallel thereto. This plate is fixed on to the face of the printed circuit board opposite that receiving the electronic components. It makes it possible to conduct the heat to be discharged from the printed circuit board to a heat exchanger positioned in the cabinet and pressed against the thermal drain, for example in the form of channels or of plates in which a coolant circulates. It is then necessary to connect these channels or plates to a cooling network external to the equipment item.

This solution is suited to applications equipped with such a cooling network. On the other hand, this type of solution proves to be insufficiently effective for the applications in which the cabinets are not equipped with a cooling network and which are generally equipped only with a fan.

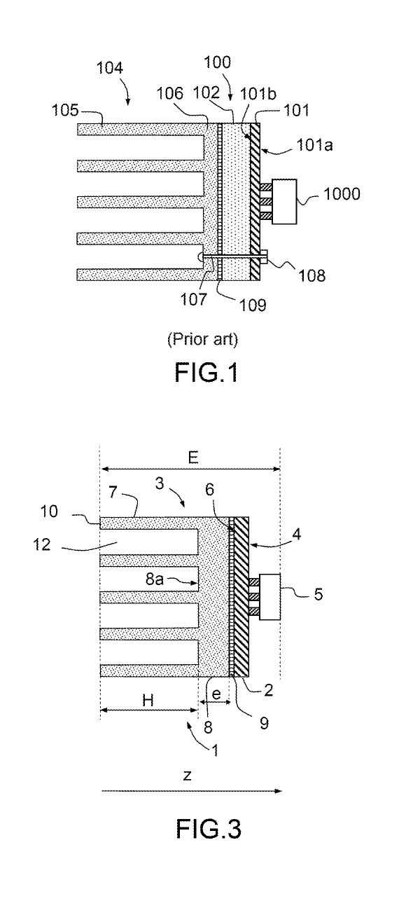

To correct this drawback, it is conventional practice to screw a heat sink comprising cooling fins on to the face of the thermal drain opposite the printed circuit board. The heat sink, through its fins, increases the contact surface between the electronic circuit board and the fluid in contact with the electronic circuit board, for example air. It makes it possible to improve the convection cooling performance levels. A solution of this type is represented in FIG. 1 in which can be seen the electronic circuit board 100 comprising a printed circuit board 101 comprising two faces 101a and 101b, a drain 102 fixed to the printed circuit board 101 (and more specifically to the second face 101b of the printed circuit board 101a), a component 1000 fixed to the printed circuit board 101 (and more specifically soldered on to the first face 101a), a heat sink 104 comprising cooling fins 105 and a base 106 that is thin relative to the thermal drain. The heat sink 104 is fixed to the drain 102 and to the printed circuit board 101 by means of a plurality of screw 107—nut 108 systems, typically at least ten or so, only one of which is visible in FIG. 1, the screw 107 passing through the drain 102 and the printed circuit board 101, and a layer of thermal grease 109 interposed between the heat sink 104 and the drain 102 and ensuring a good heat exchange between the heat sink 104 and the drain 102 by filling the interstices between these two elements.

The applicant has found that this type of board presents a certain number of drawbacks. The grease is made up of a mixture of two phases comprising a liquid phase (oil) which is a grease and a solid phase comprising conductive particles usually of silver. These two phases separate in time and with temperature increases which causes the energy dissipation performance levels of the heat sink plus drain system to be diminished and can limit the performance levels of the other boards or equipment items inserted into the cabinet, even degrade their performance levels. The fixing of the heat sink 104 to the thermal drain 102 by means of the screw-nut systems 107-108 considerably limits the useful surface of the printed circuit board. It is in fact necessary to provide an adequate isolation zone between each screw-nut system and the components on the face 101a of the printed circuit board receiving the components.

Moreover, the operations of fixing of the heat sink on to the thermal drain and of application of the thermal grease are difficult operations that have to be performed manually, which are consequently costly.

Furthermore, the screw-nut systems disrupt the flow of air on the heat sink side which causes the control of the cooling of the electronic plate to be reduced.

Finally, this type of solution exhibits a significant thickness.

The aim of the invention is to correct all or part of the abovementioned drawbacks.

To this end, the subject of the invention is an electronic circuit board comprising an assembly of a printed circuit board comprising a first face receiving at least one electronic component, and of a heat sink, the printed circuit board and the heat sink being stacked in a stacking direction, said heat sink being fixed to the printed circuit board on a second face opposite the first face, said heat sink comprising a base, in the form of a plate, and reliefs extending from a flat surface of said base, the reliefs being intended to increase the contact surface between the heat sink and a flow of air relative to the contact surface between the base and the flow of air, the base being interposed between the printed circuit board and the reliefs in the stacking direction. The heat sink is fixed directly to the printed circuit board by gluing only and said heat sink is of a single piece. Advantageously, only an adhesive layer separates the base and the printed circuit board, the adhesive layer comprising a glue extending continually from the base to the printed circuit board.

Advantageously, the adhesive layer is a film of glue.

Advantageously, the adhesive layer comprises glue-impregnated fibres.

Advantageously, the adhesive layer is an electrical insulator.

Advantageously, the glue is a thermosetting glue.

Advantageously, the heat sink is made of metal.

Advantageously, the adhesive layer is less than or equal to 200 micrometres and preferably between 100 micrometres and 200 micrometres.

Advantageously, the heat sink has a thickness of between 5 mm and 20 mm.

Advantageously, the printed circuit board has a thickness of between 0.1 mm and 1 mm.

Advantageously, the heat sink extends substantially over all the useful surface of the printed circuit board.

Advantageously, the heat sink is fixed to the printed circuit board by gluing by means of a film of glue interposed between the base the printed circuit board in the stacking direction.

The invention relates also to a method for manufacturing an electronic circuit board comprising:
a stacking step in which the heat sink is positioned such that the base is interposed between the reliefs and the second face of the printed circuit board and in which an adhesive layer is arranged between the second face of the printed circuit board and the base, the adhesive layer comprising a glue extending continually over all the thickness of the glue in the stacking direction,
an assembly step consisting in assembling the heat sink and the printed circuit board in which the stacking obtained is subjected to a hot compression.

Advantageously, the assembly step is performed by means of a press comprising a tool comprising a portion configured and arranged relative to the heat sink so as to come to bear on the surface from which the reliefs extend and extending between the reliefs.

Advantageously, the assembly step is performed by means of a press comprising a tool comprising a portion configured and arranged relative to the heat sink so as to come to bear on all of the surface from which the reliefs extend and extending between the reliefs.

Advantageously, the assembly step is performed by means of a press comprising a tool comprising a portion configured and arranged relative to the heat sink so as to come to bear on the reliefs in the direction z.

Advantageously, the printed circuit board is multilayer and in which the assembly step is a step of assembly of a plurality of layers of the printed circuit board.

Advantageously, the assembly of the heat sink and of the printed circuit board is performed by polymerization of the glue.

Other features and advantages of the invention will become apparent on reading the following detailed description, given as a nonlimiting example and with reference to the attached drawings in which:

FIG. 1, already described, schematically represents, in cross section, an electronic circuit board of the prior art,

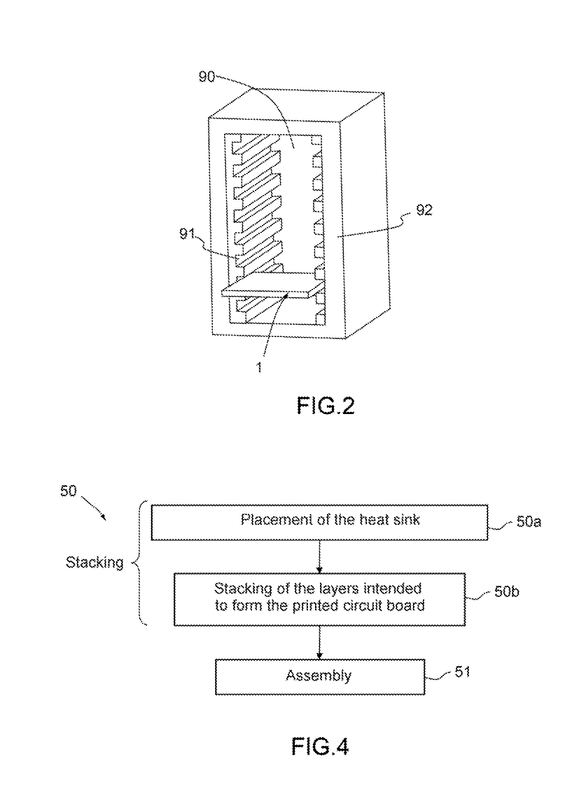

FIG. 2 schematically represents a cabinet receiving an electronic circuit board according to the invention on which the electronic components and the heat sink have not been represented for greater clarity,

FIG. 3 schematically represents a cross section of an electronic circuit board according to the invention,

FIG. 4 represents a block diagram of the steps of the method according to the invention,

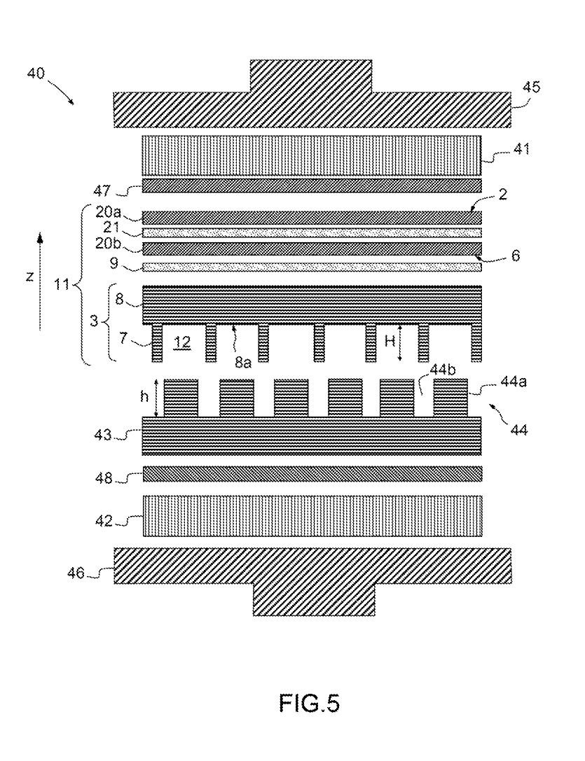

FIG. 5 schematically represents a press used in the method according to the invention.

From one figure to another, the same elements are identified by the same references.

FIG. 2 represents a cabinet 90 comprising a plurality of runners 91 extending longitudinally parallel to one another. The cabinet 90 receives an electronic circuit board 1 according to the invention. The electronic circuit board 1 is held in the frame 92 of the cabinet 90 in runners 91 at right angles to the backplane.

FIG. 3 represents, in perspective, a cross section of an electronic circuit board according to the invention along a plane parallel to the stacking direction.

The electronic circuit board 1 comprises an assembly of a printed circuit board 2 and a heat sink 3. The printed circuit board 2 is of the type comprising a plurality of individual layers not represented in FIG. 1. It comprises at least one conductive layer and at least one insulating layer. Each conductive layer comprises electrically conductive tracks. These tracks are conventionally made of copper. As a variant, the tracks are produced in a material other than copper. The printed circuit board can be of the single-sided type (comprising one conductive layer and one insulating layer), double-sided type (comprising two conductive layers separated by one insulating layer), or multilayer type (comprising at least three conductive layers separated in pairs by one insulating layer). The conductive layers are for example formed from layers of copper. These layers of copper, or individual conductive layers of the printed circuit board are for example etched so as to form tracks. An insulating layer should be understood to be an electrically insulating layer and a conductive layer should be understood to be an electrically conductive layer.

The printed circuit board 2 comprises a first face 4 intended to receive one or more electronic components. Just one electronic component 5 can be seen in FIG. 3. The first face 4 can receive several electronic components. All the electronic components fixed on to the printed circuit board 2 are received by the first face 4. In other words, each electronic component is fixed, preferably soldered, on to the first face 4.

The printed circuit board 2 and the heat sink 3 are stacked in a stacking direction z. The individual layers, not represented, of the printed circuit board 2 are also stacked in the stacking direction z. The heat sink 3 is fixed to the printed circuit board on a second face 6 of the printed circuit board 2. The second face 6 is opposite the first face 4. The first and second faces are parallel to one another and at right angles to the stacking direction z.

The heat sink 3 extends substantially over all the useful surface of the printed circuit board. In other words, the heat sink can extend over all the surface of the printed circuit board or else, as a variant, extend over the useful surface of the printed circuit board extending between two runners holding the printed circuit board in the cabinet without extending into the two runners.

The heat sink 3 comprises cooling fins 7 and a base 8. The base 8 is interposed between the cooling fins 7 and the printed circuit board 2 in the stacking direction z. The heat sink 3 has a profile in the form of a comb in the plane of the figure. The base 8 ensures a thermal drain function making it possible to discharge the heat transmitted by the components to the printed circuit board 2 from the second face 6 of the printed circuit board 2 to the fins 7.

The base 8 has the form of a plate. The plate extends according to its thickness e, parallel to the stacking direction z. It is pressed against the printed circuit board. The base 8 is thick in relation to the printed circuit board 2. The printed circuit board 2 typically has a thickness of between 0.10 and 1 mm. The base 8 has a thickness at least equal to 2 mm. Typically, the base 8 has a thickness of between 2 and 5 mm. However, this range is not limiting in as much as the dimensions of the base and of the cooling fins are determined as a function of the thickness of the printed circuit board, as a function of the thickness of the electronic circuit board desired and as a function of the desired thermal performance levels.

In a particular embodiment, the heat sink 3 ensures a printed circuit board 2 stiffener function. In this case, the base 8 has a stiffness greater than that of the printed circuit board. As a variant, the printed circuit board has a stiffness at least equal to the base of the heat sink.

The cooling fins 7 make it possible to improve the discharge of the heat (dissipated by the printed circuit board 2 because of the heating up of the components) by convection relative to a heat sink in the form of a plate by increasing the contact surface between the heat sink and the fluid in contact therewith relative to the contact surface between the base 8 and the flow of air, that is to say the free surface of the base. In other words, a heat sink comprising cooling fins, that is to say formed by the base provided with the cooling fins, presents with the air a contact surface greater than that of a heat sink comprising only the base. Each fin 7 has the form of a plate extending longitudinally in a direction parallel to a direction at right angles to the plane of FIG. 3 and having, in the plane of FIG. 3, the form of a rod extending longitudinally, in the stacking direction z, from the base 8 to a free end 10 according. The fins 7 extend from a flat surface 8a of the base opposite the printed circuit board 2 in the stacking direction z. The flat surface 8a is discontinuous. It is formed by a plurality of portions separated by the fins. The fins 7 have a height H typically at least equal to 2 mm and typically between 2 and 15 mm. As for the base, this range is not limiting since the dimensions of the base depend on several parameters as explained previously. The plane of FIG. 3 is a plane containing the stacking direction and at right angles to the longitudinal direction of the fins. The height of the fins H of the fins is the direction of the fins in the stacking direction z.

The fins 7 are separated in pairs by trenches 12. The trenches 12 extend longitudinally parallel to the longitudinal direction of the fins. The trenches have a U-section in the plane of FIG. 3. The bottom of each U is formed by a portion of the surface 8a of the base 8 opposite the printed circuit board 2 and the arms of each U are formed by two adjacent fins 7. The section of the fins is constant. In other words, they have dimensions that are constant along the direction in which they extend longitudinally (direction at right angles to the plane of FIG. 3). Consequently, the trenches also have a constant section.

According to the invention, the heat sink 3 is of a single piece. In other words, the fins 7 and the base 8 are formed in a single piece. That means that the heat sink 3 is produced in a single material. This material can be homogenous. As a variant, it is composite.

This part is preferably, but not necessarily, solid, as opposed to hollow. The heat sink can be produced in a material exhibiting a strong thermal conductivity. It is for example produced in metal, preferably in aluminium, or in copper. According to the invention, the heat sink is fixed directly to the printed circuit board 2 only by gluing. In other words, the heat sink 3 is fixed to the printed circuit board by means of a film of glue 9 interposed between the heat sink and the printed circuit board 2. More specifically, the film of glue 9 is interposed between the base 8 and the printed circuit board 2. “Heat sink fixed directly to the printed circuit board by gluing” should be understood to mean that the printed circuit board and the heat sink are separated only by a film of glue 9.

More generally, according to the invention the heat sink is fixed to the printed circuit board by means of an adhesive layer. The printed circuit board and the sink are separated only by this adhesive layer.

Advantageously, the adhesive layer comprises a glue which extends continually from the printed circuit board to the base.

The adhesive layer can be a glue, that is to say a film of glue. As a variant, the adhesive layer is a fibrous layer comprising glue-impregnated fibres. The fibres are, in a nonlimiting example, glass fibres.

In this type of adhesive layer, the glue passes advantageously between the fibres such that it extends continually from the printed circuit board to the base. The fibrous layer can be a glue-impregnated fabric, in other words it comprises glue-impregnated woven fibres. As a variant, the fibrous layer is a glue-impregnated mat. This type of adhesive layer offers the advantage of being easy to apply.

Preferably but not necessarily, the glue is in contact with the printed circuit board and the heat sink substantially over all the surface of the heat sink.

Advantageously, the gluing of the heat sink to the printed circuit board is performed by polymerization of the glue. The adhesive layer then comprises polymers.

The film of glue 9, or more generally the adhesive layer, is an electrical insulator. In other words, this layer is produced in an electrically insulating material. More specifically, it is produced in one or more materials which is (are) electrically insulated. That makes it possible to avoid the formation of a short-circuit between the printed circuit board (in particular with the layer of the printed circuit board which is facing the film of glue) and the heat sink conventionally forming the mechanical ground.

In the case of a fibrous layer, the glue and the fibres are formed in electrically insulating materials. In the case of the film of glue, the glue is an electrical insulator.

The film of glue, or more generally the adhesive layer, has a thickness less than or equal to 200 micrometres. It preferably has a minimum thickness of 100 micrometres and typically between 100 and 200 micrometres. It makes it possible to effectively compensate for the surface defects of the base and of the heat sink.

The glue is, preferably but not necessarily, thermosetting. The adhesive layer extends over all the surface of the base 8 facing the printed circuit board. These features are linked to the assembly method used and described hereinafter in the text. The reduced thickness of the film of glue allows a very effective heat transfer between the printed circuit board and the heat sink 3. Moreover, the adhesive layer makes it possible to limit the risks of formation of air bubbles by penetrating into the unevennesses of the two surfaces. It can be used to fix together large surfaces and at low temperature making it possible to preserve the integrity of the printed circuit board.

The glue is preferably produced based on epoxy resin or is of the acrylic glue type. As a variant, in a nonlimiting manner, the glue is a polyurethane, cyanoacrylate, elastomer or silicone glue.

The fact that the heat sink, ensuring the dual function of discharging of the heat by thermal convection (fins) and thermal conduction (drain or base) is of a single piece and fixed only by gluing to the printed circuit board provides a certain number of advantages. It can be fixed in a single non-manual step of gluing to the printed circuit board, which limits the cost of the assembly of the electronic circuit board and makes it possible to offer a surface for locating the electronic components 5 that is significant on the side of the first face 4 of the printed circuit board 2. The heat sink 3 has a single interface with the printed circuit board 2 (film of glue 9 or adhesive layer) which means that the thermal transfer between these two elements is better than when the heat sink is of the type comprising a base and a heat sink linked together by screws and separated by a thermal grease. This increasing of the performance levels in terms of thermal energy dissipation makes it possible, for a given printed circuit board, given electronic components and given performance levels in terms of discharging of the heat, to reduce the thickness of the heat sink. The thickness of the heat sink is given by the thickness of the base 8 and the height H of the cooling fins 7. The invention typically makes it possible to produce electronic circuit boards that can go into the space allotted for a single electronic circuit board in a rack or drawer according to the VME64 standard while obtaining the performance levels in terms of heat dissipation that are desired, in particular for a power supply board which was not possible with the devices of the prior art. Typically, the heat sink has a thickness of between 5 and 20 mm in the stacking direction which makes it possible to produce electronic circuit boards that have a thickness E less than or equal to 20.32 mm in the stacking direction corresponding to the thickness allotted to an electronic circuit board in the VME standard. The electronic circuit board according to the invention has a limited weight.

Moreover, the invention makes it possible to assemble the heat sink in a single assembly step which can be the step of assembly of the printed circuit board in the case of a multilayer printed circuit board. In this last case, the fixing of the heat sink on to the printed circuit board is not an additional assembly step subsequent to the step of assembly of the printed circuit board.

The invention has been described with reference to an embodiment in which the heat sink comprises cooling fins. These fins are reliefs, that is to say structures protruding on a flat surface 8a of the base 8. The reliefs are intended to increase the contact surface between the heat sink 3 and a flow of air relative to the contact surface between the base 8 (without relief) and the flow of air. This embodiment is nonlimiting. An embodiment is envisaged in which the reliefs take the form of pins, that is to say posts or rods extending longitudinally in the stacking direction. The pins extend longitudinally in the stacking direction z from the base 8 to a free end. As a variant, the heat sink comprises at least one cooling fin and at least one pin.

More generally, the invention relates to an electronic circuit board in which the heat sink comprises a base 8 as described previously and reliefs on the surface of said base, the reliefs being intended to increase the contact surface between the heat sink and a flow of air relative to the contact surface between the base and the flow of air. The reliefs extend from a flat surface 8a of the base in the stacking direction z. More specifically, these reliefs extend from the flat surface 8a which is the surface of the base opposite the printed circuit board in the stacking direction z. The flat surface 8a extends between the reliefs. The flat surface 8a is discontinuous when the reliefs are fins and continuous when the reliefs are pins. The reliefs are for example, but in a nonlimiting manner, pins or fins.

Everything that has been stated previously with the cooling fins is also valid with the pins and, generally, with the reliefs on the surface of the base.

The invention relates also to a method for manufacturing an electronic circuit board 1 according to the invention.

FIG. 4 represents a block diagram of the steps of the method according to the invention.

The method for manufacturing the electronic circuit board according to the invention comprises:
a step of stacking 50, in the stacking direction, comprising a first step 50a consisting in placing the heat sink 3 such that the base 8 is interposed between the reliefs which are for example fins 7 and the second face 6 of the printed circuit board 2 and in arranging a layer of glue 9, or more generally the adhesive layer, between the second face 6 of the printed circuit board and the base 8,
an assembly step 51 of the heat sink 3 and of the printed circuit board 2 during which the stacking obtained in the stacking step 50 is subjected to a hot compression.

The assembly step 51 is performed so as to assemble the base to the printed circuit board by gluing by means of the adhesive layer comprising the glue. In the assembly step 51, the printed circuit board is advantageously glued to the heat sink by polymerization of the glue.

Advantageously, the glue hardens during the assembly step. It is liquid, pasty or viscous when the adhesive layer is applied during the stacking phase 50.

During the stacking step 50, an adhesive layer is deposited comprising a glue extending continually over all the thickness of the adhesive layer, in the stacking direction.

In the stacking step 50, the heat sink 3 and the printed circuit board 2 or the layers intended to form the printed circuit board 2 and the heat sink are stacked in the stacking direction z so as to obtain a stacking 11. In the stacking step 50, the layer of glue 9 or the adhesive layer is applied to the second face 6 of the printed circuit board 2 and/or to the face of the base 8 facing the second face 6 of the printed circuit board 2. In the assembly step 51, the compression is performed in the stacking direction z. Hot compression should be understood to mean a step of compression of the stacking during which the stacking obtained is heated up.

The electronic components 5 are then added to the printed circuit board 2 and more specifically to the second face of the printed circuit board. Advantageously, the tracks are etched prior to the step 50.

Advantageously, the printed circuit board 2 is a multilayer printed circuit board. The stacking step 50 comprises a second step 50b of stacking of a plurality of layers intended to form the multilayer circuit in the stacking direction z. These layers are double-sided assemblies.

The step of assembly 51 of the heat sink 3 and of the printed circuit board 2 is then advantageously a step of assembly of the printed circuit board 2, that is to say a step of assembly of the double-sided assemblies intended to form the multilayer printed circuit board, that is to say a step of assembly of a plurality of layers of the printed circuit board. The assembly step 51 is performed by pressing the stacking obtained in the step 50 in the stacking direction. It is a step called lamination. As a variant, the printed circuit board is multilayer but the layers or some of the layers of the printed circuit board are assembled before the assembly step 51. Such is the case, for example, when layers have to be interconnected with one another. They are assembled prior to the step of assembly of the heat sink with the printed circuit board.

FIG. 5 schematically represents a press 40 making it possible to perform the assembly step 51 of the method according to the invention. In this embodiment, the reliefs are fins.

The press 40 comprises two tools 41, 42. The stacking is performed between these two tools 41, 42. Each tool 41, 42 consists of a plate a face 41a, 42a positioned facing the stacking 11. The press comprises a load take-up tool 43. The tool is adjacent to the heat sink so as to come to bear on it during the pressing. The tool 43 comprises a portion 44 having a form substantially complementing the part of the heat sink 3 opposite the printed circuit board 2 in the direction z. In other words, the portion 44 of the tool 43 has a form substantially complementing the part of the heat sink formed by the cooling fins 7 and the surface 8a of the base 8 from which they extend. In the assembly step 51, the heat sink 3 and the tool 43 cooperate such that the portion 44 substantially forms the die of the part of the heat sink 3 opposite the printed circuit board, that is to say of the part of the heat sink 3 formed by the cooling fins 7 and by the surface of the base from which they extend. In other words, the portion 44 of the tool 43 substantially matches the form of the cooling fins 7 and of the surface 8a from which they extend.

In other words, the tool 43 has a portion 44 intended to cooperate with the heat sink. This portion 44 has fins of the tool 44a separated in pairs by trenches 44b of the tool 44b. The trenches of the tool 44a and the fins of the tool 44b are configured and arranged relative to one another such that the portion 44 has a form substantially complementing that formed by the fins 7 and the trenches 12 of the heat sink 3. In the nonlimiting embodiment of FIGS. 3 and 5, the fins 7 have the same dimensions in the plane of FIG. 3 and are evenly spaced apart, in a direction at right angles to the stacking direction z in the plane of FIG. 3, and separated by trenches 12 all having the same dimensions in the plane of FIG. 3. The fins of the tool 44a consequently have a section substantially identical to that of the trenches 12 and the trenches of the tool have dimensions substantially identical to those of the fins 7.

In the step 51, the tool 43 and the heat sink 3 are positioned relative to one another such that the fins of the tool 44a penetrate into the trenches 12 and the fins 7 penetrate into the trenches of the tool 44a. The tool then comes to bear on all of the surface 8a from which the fins 7 extend and on the fins 7 in the pressing step.

The tools 41, 42, 43 are for example parts made of steel or of aluminium. The tool 43 is preferably produced in a material exhibiting a thermal expansion coefficient substantially identical to that of the heat sink 3 between ambient temperature and the heating temperature.

The tools 41, 42, 43 are then transferred in the compartments of the plate press 40. The plates 45, 46 can be brought together and separated from one another using a device that is not represented, for example of the type comprising cylinder actuators. The tools 41, 42, 43 are compressed, in the stacking direction z, by bringing the two plates 45, 46 closer to one another in the stacking direction z. A heating circuit that is not represented ensures the heating of the tools 41, 42, 43 or 41, 43 using a heating circuit at least partially incorporated in the plates 45, 46 so as to heat up the stack 11 obtained in the step 50.

Advantageously, a deformable mat 47, 48 is interposed between the tool 41 and the layers 20a, 20b intended to form the printed circuit board 2 and between the tool 42 and the tool 43.

Advantageously, the pressure applied to the stacking 11 in the assembly step 51 is typically between 30 and 40 bar and the stacking is heated up to a temperature typically lying between 120 and 180° C. The temperature applied depends on the polymerization temperature of the glue used. The pressure and the temperature are applied for a duration typically lying between 1 h30 and 3 h30. This duration depends on the polymerization cycle of the glue used.

In the embodiment of FIG. 5, a plurality of layers 20a, 20b intended to form the printed circuit board 2 are stacked in the direction z. These layers are typically double-sided. A layer of glue 21 is interposed between these two layers, that is to say applied to at least one of the two layers facing one another.

The form of the tool 43 makes it possible to produce a powerful fixing of the heat sink 3 on to the printed circuit board 2 without deformation of the cooling fins 7 and without warping the assembly formed by the printed circuit board 2 and the heat sink 3. It makes it possible to apply a substantially uniform pressure over all the surface of the heat sink in a plane at right angles to the stacking direction which ensures a gluing of the heat sink on to the printed circuit board over all the surface of the face of the heat sink situated facing the printed circuit board. It makes it possible to avoid the formation of air bubbles at the interface between the heat sink 3 and the printed circuit board 2. That makes it possible to limit the risks of delamination of the electronic circuit board and thus a diminishing of its performance level over time under the effect of temperature changes.

More generally, the assembly step 51 is performed by means of a press comprising a tool 42 comprising a portion 44 configured so as to exhibit a form substantially complementing the part of the heat sink 3 formed by the reliefs 7 and by the surface 8a, of the base 8, from which they extend. Moreover, during this step, the heat sink 3 and the tool 42 are arranged so as to cooperate in such a way that the portion 44 of the second tool 42 substantially forms the die of the part of the heat sink 3 formed by the reliefs 7 and by the surface 8a, of the base 8, from which they extend.

A portion 44 of the tool 43 substantially forms the die of the part of the heat sink 3 formed by the reliefs 7 (or fins) and by the surface 8a of the base 8 from which the reliefs extend should be understood to mean that the portion 44 has a form complementing the reliefs 7 and the surface 8a within operating play tolerances. The operating play tolerance is defined so as to avoid jams between the tool 43 and the heat sink 3 during the pressing, that is to say during the step 51, and so that the tool 43 comes to bear on all of the surface of the reliefs and of the surface 8a extending between the reliefs. In other words, in the assembly step 51, the heat sink and the tool 43 are deformed so as to fill the play tolerances between them. The tool is configured and positioned relative to the heat sink so as to come to bear on all of the surface 8a and on the reliefs 7 in the direction z.

In a variant, the portion 44 of the tool 43 forms, in the step 51, substantially the die of the at least one hollow part 12 extending between the reliefs 7 and being delimited by the surface 8a. In other words, the portion 44 is configured and arranged relative to the heat sink 3 so as to have at least one relief substantially complementing the at least one hollow part extending between the reliefs 7. This complementarity is produced to within an operating play tolerance so as to avoid jams between the tool 43 and the heat sink 3 during the pressing, that is to say in the step 51 and such that the tool 43 comes to bear on all of the surface 8a extending between the reliefs. Consequently, the portion 44 is configured and arranged relative to the heat sink, in the step 51, so as to come to bear on all of the surface 8a from which the reliefs 7 extend. In a less advantageous variant, the form of the portion 44 is defined such that it comes to bear on a part of the surface 8a.

In the case of a heat sink with pins, the portion of the tool has a relief extending continually between the pins and in the case of a heat sink 3 with fins 7, the portion 44 comprises several reliefs (or fins) 44a substantially complementing the grooves 12. For example, the height h of the reliefs of the tool 43 is greater than that of the reliefs 7 of the heat sink and defined such that the play tolerance between the tool and the reliefs is not taken up in the pressing step. That makes it possible to avoid having the fins 7, the most fragile part of the heat sink, support the pressing force. That makes it possible to achieve a good uniformity of gluing on the surface of the heat sink between the reliefs 7.

The method according to the invention makes it possible to obtain an electronic circuit board in which the film of glue or more generally the adhesive layer has a thickness typically of between 100 and 200 micrometres. That makes it possible to guarantee a good heat transfer efficiency between the heat sink 3 and the printed circuit board 2. Moreover, the glue overflows around the heat sink in a plane at right angles to the stacking direction z. This overflowing is due to a creeping of the glue in the step 51. Moreover, the glue is advantageously polymerized.

The tool 43 described can be used even when the printed circuit board is not multilayer.

The ranges given in the present patent application are preferential ranges but they are nonlimiting, the measurements, durations, can be situated outside these ranges.

1. An electronic circuit board comprising an assembly of a printed circuit board comprising a first face receiving at least one electronic component, and of a heat sink, the printed circuit board and the heat sink being stacked in a stacking direction, said heat sink being fixed to the printed circuit board on a second face opposite the first face, said heat sink comprising a base, in the form of a plate, and reliefs extending from a flat surface of said base, the reliefs being intended to increase the contact surface between the heat sink and a flow of air relative to the contact surface between the base and the flow of air, the base being interposed between the printed circuit board and the reliefs in the stacking direction, wherein the heat sink is fixed to the printed circuit board by gluing only such that only an adhesive layer separates the base and the printed circuit board, the adhesive layer comprising a glue extending continually from the base to the printed circuit board, and wherein said heat sink is of a single piece.

2. The electronic circuit board according to claim 1, wherein the adhesive layer is a film of glue.

3. The electronic circuit board according to claim 1, wherein the adhesive layer comprises glue-impregnated fibres.

4. The electronic circuit board according to claim 1, wherein the adhesive layer is an electrical insulator.

5. The electronic circuit board according to claim 1, wherein the glue is a thermosetting glue.

6. The electronic circuit board according to claim 1, wherein the heat sink is made of metal.

7. The electronic circuit board according to claim 1, wherein the adhesive layer has a thickness of less than or equal to 200 micrometres.

8. The electronic circuit board according to claim 7, wherein the adhesive layer has a thickness of between 100 micrometres and 200 micrometres.

9. The electronic circuit board according to claim 1, wherein the heat sink has a thickness of between 5 mm and 20 mm.

10. The electronic circuit board according to claim 1, wherein the printed circuit board has a thickness of between 0.1 mm and 1 mm.

11. The electronic circuit board according to claim 1, wherein the heat sink extends substantially over all the useful surface of the printed circuit board.

12. A method for manufacturing an electronic circuit board according to claim 1, comprising:
a step of stacking in the stacking direction, wherein the heat sink is positioned such that the base is interposed between the reliefs and the second face of the printed circuit board and wherein an adhesive layer is arranged between the second face of the printed circuit board and the base, the adhesive layer comprising a glue extending continually over all the thickness of the glue in the stacking direction,
an assembly step of assembling the heat sink and the printed circuit board wherein the stacking obtained is subjected to a hot compression.

13. The method for manufacturing an electronic circuit board according to claim 12, wherein the assembly step is performed by means of a press comprising a tool comprising a portion configured and arranged relative to the heat sink so as to come to bear on the surface from which the reliefs extend and extending between the reliefs.

14. The method for manufacturing an electronic circuit board according to claim 13, wherein the assembly step is performed by means of a press comprising a tool comprising a portion configured and arranged relative to the heat sink so as to come to bear on all of the surface from which the reliefs extend and extending between the reliefs.

15. The method for manufacturing an electronic circuit board according to claim 12, wherein the assembly step is performed by means of a press comprising a tool comprising a portion configured and arranged relative to the heat sink so as to come to bear on the reliefs in the direction z.

16. The method for manufacturing an electronic circuit board according to claim 12, wherein the printed circuit board is multilayer and wherein the assembly step is a step of assembly of a plurality of layers of the printed circuit board.

17. The method according to claim 12, wherein the assembly of the heat sink and of the printed circuit board is performed by polymerization of the glue.
